(19) United States
(12) Patent Application Publication
(10) Pub. No.: US 2007/0254425 A1
(43) Pub. Date: Nov. 1, 2007

(54) Methods of fabricating a semiconductor device

(76) Inventors: Sang-Yong Kim, Yongin-si (KR); Mong-Sup Lee, Suwon-si (KR); Chang-Ki Hong, Seongnam-si (KR); Woo-Gwan Shim, Yongin-si (KR)

Correspondence Address: HARNESS, DICKEY & PIERCE, P.L.C., P.O. BOX 8910, RESTON, VA, 20195, US

(21) Appl. No.: 11/654,543

(22) Filed: Jan. 18, 2007

(30) Foreign Application Priority Data
Jan. 18, 2006 (KR) 10-2006-0005554

(51) Int. Cl. H01L 21/8238

(52) U.S. Cl. 438/216; 257/E21.632

(57) ABSTRACT

Example embodiments of the present invention relates to methods of fabricating a semiconductor device. Other example embodiments of the present invention relate to methods of fabricating a semiconductor device using a metal nitride layer as a gate electrode. The methods may include providing a semiconductor substrate having a first region and a second region. A gate insulating layer, a metal nitride layer and/or an amorphous carbon layer may be sequentially formed on the substrate. The amorphous carbon layer may be selectively etched, forming an amorphous carbon mask covering the first region. The metal nitride layer, exposed by the amorphous carbon mask, may be etched, forming a preliminary metal nitride pattern. The amorphous carbon mask may be removed.

### PRIORITY STATEMENT

This application claims the benefit of priority under 35 U.S.C. § 119 from Korean Patent Application No. 10-2006-0005554, filed Jan. 18, 2006, in the Korean Intellectual Property Office (KIPO), the disclosure of which is hereby incorporated herein by reference in its entirety.

### BACKGROUND OF INVENTION

1. Field of the Invention

Example embodiments of the present invention relate to methods of fabricating a semiconductor device. Other example embodiments of the present invention relate to methods of fabricating a semiconductor device using a metal nitride layer as a gate electrode.

2. Description of Related Art

A transistor is a semiconductor device that may be used for amplification, switching, voltage stabilization, signal modulation and many other functions. A transistor may include a gate electrode formed on an active region of a semiconductor substrate, a gate insulating layer interposed between the gate electrode and the semiconductor substrate and source/drain regions formed on the active region at both sides of the gate electrode. The gate insulating layer may be a silicon oxide layer (SiO₂) formed by a thermal oxidation method. The gate electrode, contacting the gate insulating layer, may be a doped polysilicon layer. The transistor may be divided into an NMOS transistor and a PMOS transistor depending on a main carrier moving through a channel. In the NMOS transistor, the main carrier moving through the channel is an electron. In the PMOS transistor, the main carrier moving through the channel is a hole.

As semiconductor devices become more highly integrated, the gate insulating layer of the transistor may become smaller. The critical dimension of the gate electrode may also decrease. A thinner gate insulating layer and/or smaller critical dimension may be problematic. For example, leakage current may occur through the thinner gate insulating layer. Resistance of the gate electrode may increase according to a decrease in the critical dimension. A larger leakage current may occur in the PMOS region, compared to the NMOS region, due to a buried channel formed by doping.

In order to decrease the leakage current, the conventional art acknowledges a method of forming a gate insulating layer having a high-k dielectric layer. The high-k dielectric layer may be formed of a material having a higher dielectric constant than a silicon oxide layer. The dielectric constant of a silicon oxide layer is about 3.9. The high-k dielectric layer may be a material having a dielectric constant higher than about 3.9. When the gate insulating layer includes the high-k dielectric layer, it may be possible to form a gate insulating layer having a larger thickness compared to the silicon oxide layer, suppressing a leakage current.

In order to counteract any problems that may arise from an increase in resistance of the gate electrode, the conventional art acknowledges a method of forming the gate electrode having a metal nitride layer having a lower resistivity compared to a doped polysilicon layer. The metal nitride layer may be interposed between a gate insulating layer and a gate electrode formed on the doped polysilicon layer.

The gate electrode may be formed as a single polysilicon layer. A depletion region may be present in the gate electrode. Because the depletion region in the gate electrode may disappear, the gate electrode may be formed as a dual layer of metal nitride and polysilicon. An equivalent oxide thickness (EOT) of a high-k dielectric layer may decrease due to the gate electrode formed as the dual layer. The gate electrode formed in the dual structure may also exhibit an increase in capacitance.

When a metal layer is used for the gate electrode instead of the metal nitride layer, the metal layer may be oxidized by the high-k dielectric layer (e.g., gate insulating layer), deteriorating characteristics of a transistor.

The use of a high-k dielectric layer as a gate insulating layer and a metal nitride layer as a gate electrode are acknowledged in the conventional art.

According to the conventional art, a metal nitride layer may be formed on a substrate having a dielectric layer. The metal nitride layer may be a tantalum nitride (TaN) layer. A photosensitive layer pattern may be formed on the substrate having the metal nitride layer. The metal nitride formed of TaN may be exposed to a high density plasma using the photosensitive layer pattern as a mask. The high density plasma may be defined as a plasma having an electron density of at least 10¹¹e³¹/cm³. The dielectric layer may be a high-k dielectric material having a high dielectric constant. The high density plasma may be generated from a gas source including a combination of a primary etchant gas and a profile-control additive. The fluorine gas may be a compound selected from the group consisting of CH₄, NF₃ and SF₆ and a combination thereof. The gate electrode may be formed on the dielectric layer by exposing the metal nitride layer to the high density plasma. The high density plasma may etch the gate electrode.

The conventional methods may result in an undesirable etch profile of the metal nitride layer. The surface of the high-k dielectric layer may be damaged by the fluorine gas during the etching process of the metal nitride layer using the high density plasma. As a result, the desired characteristics of a gate insulating layer may not be obtained. In a recessed-type gate electrode, recessed portions may be also damaged.

In order to decrease the likelihood of forming an undesirable etch profile or the occurrence of damage during the etching process of the metal nitride layer using plasma, a method of removing the metal nitride layer by a wet etching process has been acknowledged.

Prior to forming a photosensitive layer pattern, a mask may be formed on the substrate having the metal nitride layer to remove the metal nitride layer. The mask may be used as an etch mask for etching the metal nitride layer. The mask may be an oxide layer. The mask may be formed using a thermal oxidation process, at a high temperature, to form the oxide layer and subsequently pattern the oxide layer. The oxide layer may be patterned to selectively cover a PMOS region. The metal nitride layer, exposed by the mask, may be removed by a wet etching process. The mask may be removed by the wet etching process. A fluoric acid solution may be used for wet-etching the mask.

When the metal nitride layer is removed using the wet etching process, problems that may occur during the plasma etching process may be resolved by a higher etch selectivity for the high-k dielectric layer. Because the oxide layer may be formed by the higher-temperature thermal oxidation method (during the wet etching process), the metal nitride layer may be denser due to the heat. As a result, an etch rate of the metal nitride layer may decrease and an etching time of the metal nitride layer may increase.

FIG. 1 is a graph illustrating the relationship between leakage current and gate electrode voltage in the conventional art.

Referring to FIG. 1, when the mask is removed using the fluoric acid solution, a relationship may be observed between the leakage current and the gate electrode voltage. During the process of removing the mask, the fluoric acid solution may pass through the metal nitride layer and may permeate to the high-k dielectric layer. As a result, damages may occur on the surface of the high-k dielectric layer. The damaged portion of the high-k dielectric layer may have an increased leakage current as illustrated in FIG. 1.

### SUMMARY OF THE INVENTION

Example embodiments of the present invention relate to methods of fabricating a semiconductor device. Other example embodiments of the present invention relate to methods of fabricating a semiconductor device using a metal nitride layer as a gate electrode.

Example embodiments of the present invention are also related to methods of fabricating a semiconductor device including forming a mask layer for etching a metal nitride layer using a low temperature process. The low temperature process may decrease the likelihood of altering characteristics of the metal nitride layer formed below the mask layer.

Other example embodiments of the present invention provide methods of fabricating a semiconductor device for reducing damages on a surface of a high-k dielectric layer when removing a mask.

In accordance with example embodiments of the present invention, a method of fabricating a semiconductor device is provided. The method may include providing a semiconductor substrate having a first region and a second region. A gate insulating layer, a metal nitride layer and/or an amorphous carbon layer may be sequentially formed on the substrate. The amorphous carbon layer may be selectively etched, forming an amorphous carbon mask covering the first region. The metal nitride layer exposed by the amorphous carbon mask may be etched, forming a preliminary metal nitride pattern. The amorphous carbon mask may be removed. The first region may be a PMOS region. The second region may be an NMOS region.

The metal nitride layer may be formed using chemical vapor deposition (CVD) process, a physical vapor deposition (PVD) process, a sputtering process or any other process known in the art. The metal nitride layer may be formed having a thickness of about 50 Å to 150 Å. The metal nitride layer may be a TaN layer or a TiN layer.

The amorphous carbon layer may be formed using a CVD process. The amorphous carbon layer may be formed having a thickness of about 2000 Å to 5000 Å. The deposition process may be performed at a temperature of about 200° C. to 400° C. After forming the amorphous carbon mask, nitrogen impurities may be implanted into the metal nitride layer exposed by the amorphous carbon mask.

The etching of the metal nitride layer may be performed using a wet etching. The wet etching may be performed at a temperature of about 25° C. to 80° C.

The amorphous carbon mask may be removed using an ashing process.

The gate insulating layer may be a high-k dielectric layer. The high-k dielectric layer may be formed of a compound selected from the group consisting of HfO₂, HfSiO, TiO₂, Ta₂O₅ and ZrO₂.

After removing the amorphous carbon mask, a conductive layer may be formed on the substrate having the preliminary metal nitride pattern. The conductive layer and the preliminary metal nitride pattern may be sequentially etched to form a conductive pattern and a metal nitride pattern, respectively. A first gate electrode having the metal nitride pattern and the conductive pattern doubly stacked may be formed in the first region. A second gate electrode may be formed in the second region. The second gate electrode may be formed from the conductive pattern.

Alternatively, the conductive layer and the preliminary metal nitride pattern may be sequentially etched, forming a first gate electrode and a second gate electrode in the first region and the second region, respectively.

After forming the first gate electrode and the second gate electrode, source/drain regions may be formed in the substrate at sides of the first gate electrode and the second gate electrode, respectively.

In accordance with other example embodiments of the present invention, another method of fabricating a transistor is provided. The method includes forming a semiconductor substrate having a first region and a third region. The first region may be a PMOS region and the third region may be a NMOS region, or vice versa. A gate insulating layer, a metal nitride layer and/or an amorphous carbon layer may be sequentially formed on the semiconductor substrate. The amorphous carbon layer may be selectively etched, forming an amorphous carbon mask covering the second region. The metal nitride layer exposed by the amorphous carbon mask may be etched, forming a preliminary metal nitride pattern. The amorphous carbon mask may be removed. A conductive layer may be formed on the surface of the substrate having the preliminary metal nitride pattern. The conductive layer and the preliminary metal nitride pattern may be etched, forming a first gate electrode in the first region and a second gate electrode in the second region. The first gate electrode may be a PMOS gate electrode and the second gate electrode may be a NMOS gate electrode, or vice versa.

The gate insulating layer may be a high-k dielectric layer. The high-k dielectric layer may be formed of a compound selected from the group consisting of HfO₂, HfSiO, TiO₂, Al₂O₃, Ta₂O₅ and ZrO₂. The metal nitride layer may be a TaN layer or a TiN layer.

The amorphous carbon layer may be formed using a CVD process. The deposition process may be performed at a temperature of about 200° C. to 400° C. The amorphous carbon layer may be formed having a thickness of about 2000 Å to 5000 Å. The amorphous carbon mask may be removed using an ashing process.

After forming the first gate electrode and the second gate electrode, source/drain regions may be formed in the substrate at sides of the first gate electrode and the second gate electrode, respectively. After forming the amorphous carbon mask, nitrogen impurities may be implanted into the metal nitride layer exposed by the amorphous carbon mask.

### BRIEF DESCRIPTION OF THE DRAWINGS

Example embodiments of the present invention will be more clearly understood from the following detailed description taken in conjunction with the accompanying drawings. FIGS. 1 and 2A-2H represent non-limiting, example embodiments of the present invention as described herein.

FIG. 1 is a graph illustrating the relationship between leakage current and gate electrode voltage in the conventional art; and

FIGS. 2A through 2H are diagrams illustrating sectional views of a method of fabricating a semiconductor device according to example embodiments of the present invention.

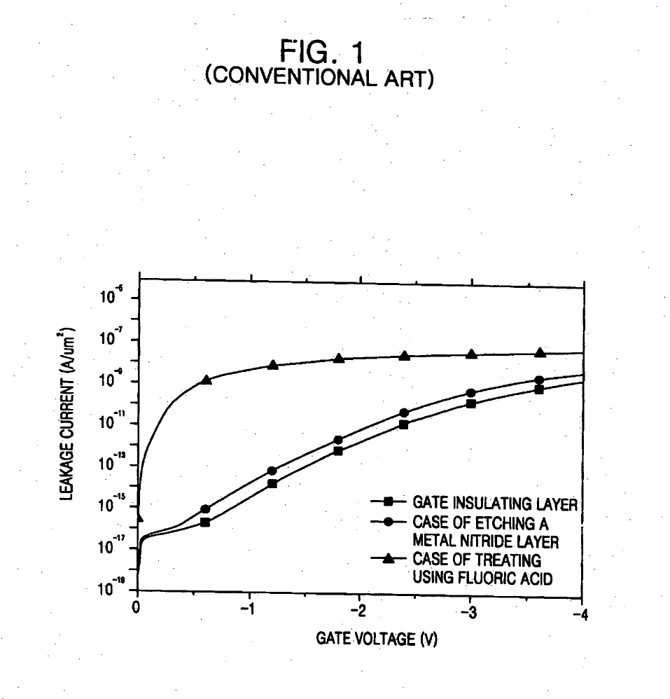

### DETAILED DESCRIPTION OF THE EXAMPLE EMBODIMENTS

Various example embodiments of the present invention will now be described more fully with reference to the accompanying drawings in which some example embodiments of the invention are shown. In the drawings, the thicknesses of layers and regions may be exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments of the present invention.

Spatially relative terms, such as “beneath”, “below”, “lower”, “above”, “upper” and the like, may be used herein for ease of description to describe one element or a feature's relationship to another element or feature as illustrated in the Figures. It will be understood that the spatially relative terms are intended to encompass different orientations of the device in use or operation in addition to the orientation depicted in the Figures. For example, if the device in the Figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Also, the use of the words “compound,” “compounds,” or “compound(s),” refer to either a single compound or to a plurality of compounds. These words are used to denote one or more compounds but may also just indicate a single compound.

Example embodiments of the present invention are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments of the invention should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope of the present invention.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments of the present invention belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments of the present invention, various aspects of the present invention will be described in detail with reference to the attached drawings. However, the present invention is not limited to the example embodiments described.

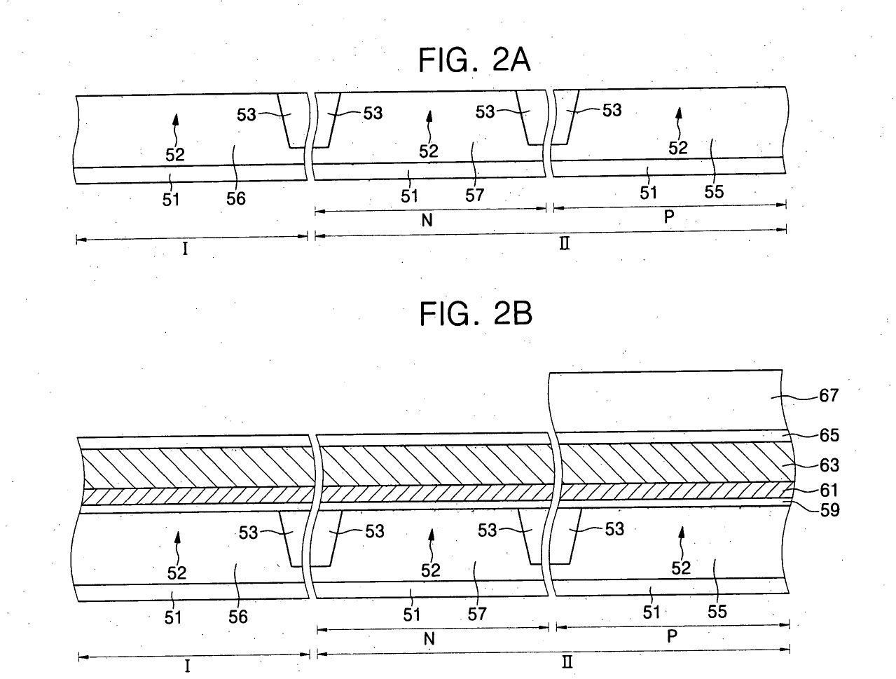

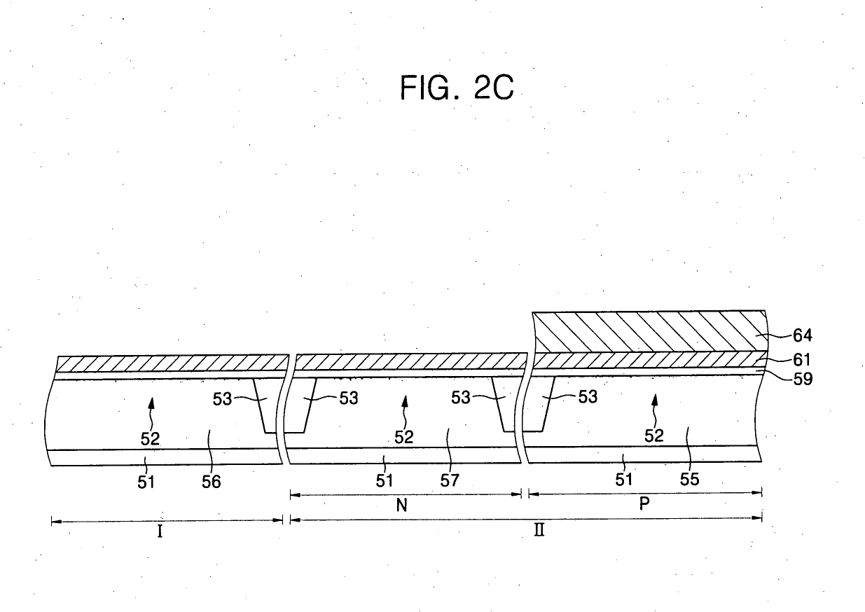

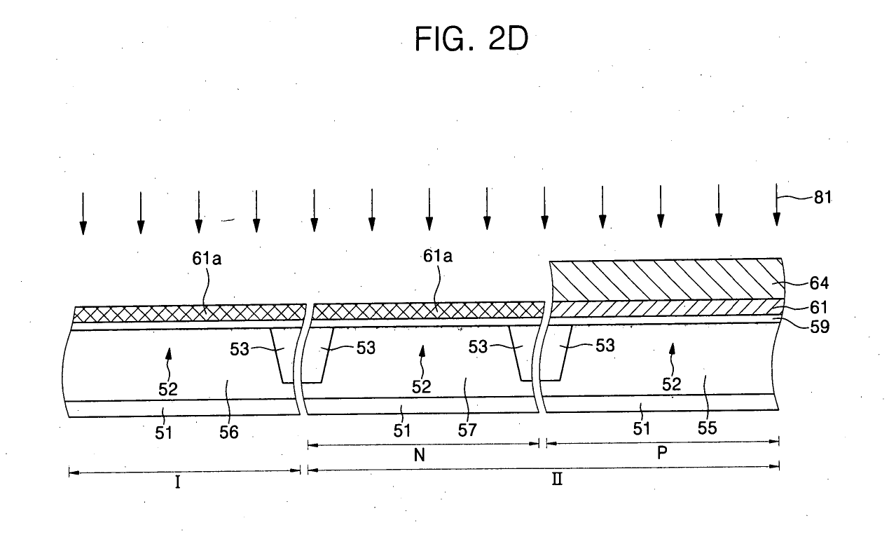

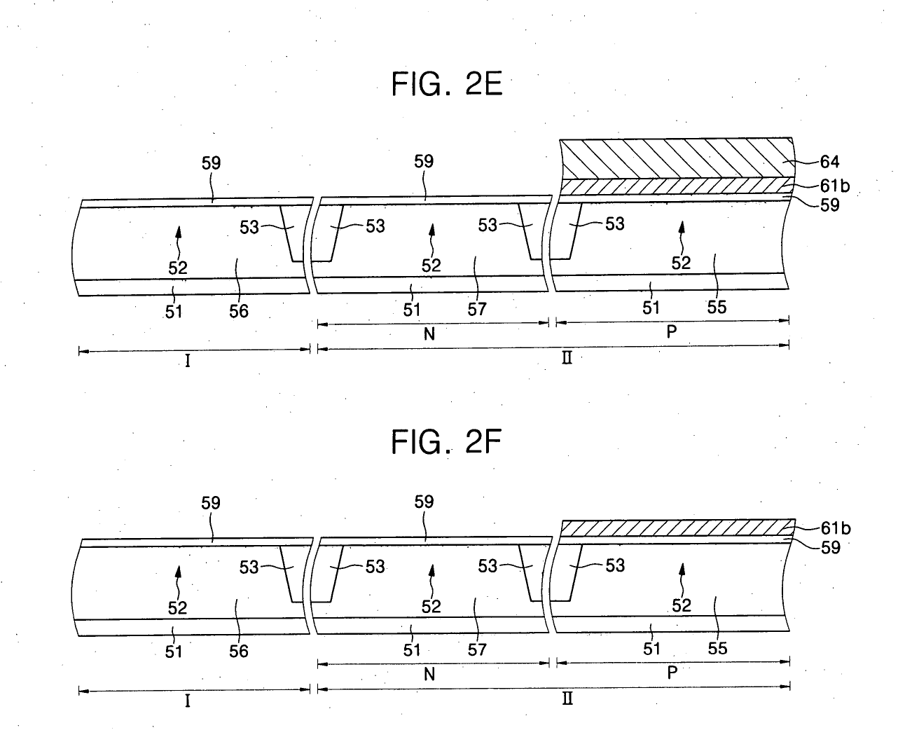

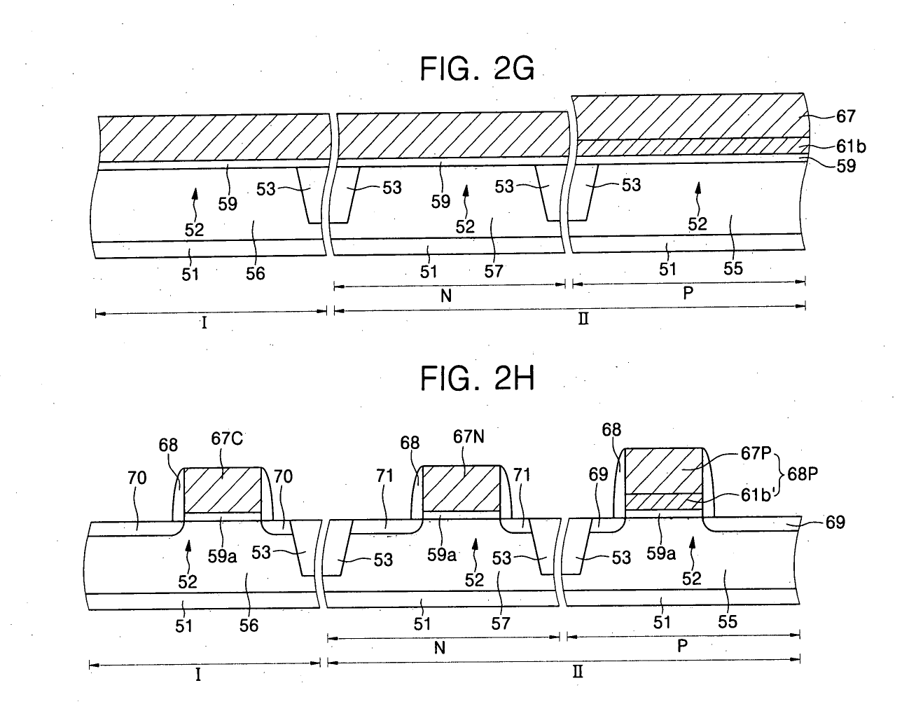

FIGS. 2A through 2H are diagram illustrating sectional views of methods of fabricating a semiconductor device according to example embodiments of the present invention.

As shown in FIG. 2A, a semiconductor substrate 51 having a cell region I and a peripheral region II is provided. The peripheral region II has a PMOS region P and an NMOS region N. The semiconductor substrate 51 may be a silicon substrate. Isolation layers 53 may be formed in the semiconductor substrate 51 to define active regions 52 of the cell region I. Isolation layers 53 may also be formed to define the PMOS region P and the NMOS region N of the peripheral region II. The isolation layers 53 may be formed using a shallow trench isolation (STI) process. A first conductivity type of impurities, or a second conductivity type of impurities, may be implanted into the substrate having the isolation layers 53, forming a first well 55 in the PMOS region P of the peripheral region II, a second well 56 in the cell region I and a third well 57 in the NMOS region N of the peripheral region II. The second well 56 and the third well 57 may be implanted with impurities having the same conductivity type. A first conductivity type of impurities may be implanted into the second well 56 and the third well 57. The first conductivity type may be an N type. For example, the first well 55 may be a P-well. The second well 56 and the third well 57 may be N-wells. The wells may be formed in other ways depending on the type of semiconductor device used. The order of formation of the isolation layers and the wells may be reversed.

As shown in FIG. 2B, a gate insulating layer 59, a metal nitride layer 61 and/or a mask layer 63 may be sequentially formed on the substrate having the wells. The gate insulating layer 59 may be a high-k dielectric layer. The “high-k dielectric” may be defined as having a k value of 100<_k or 10<k<100. The high-k dielectric layer may be formed of a compound selected from the group consisting of HfO₂, HfSiO, TiO₂, Ta₂O₅, Al₂O₃ and ZrO₂. The metal nitride layer 61 may be formed from TaN or TiN. The gate insulating layer 59 may be formed having a thickness of about 50 Å. The metal nitride layer 61 may be formed using a chemical vapor deposition (CVD) process, a physical vapor deposition (PVD) process, a sputtering process or the like. The metal nitride layer 61 may be formed having a thickness of about 50 Å to 150 Å. The metal nitride layer 61 may be formed having a thickness of about 100 Å. The mask layer 63 may be used to form an etch mask. The etch mask may be used to etch the metal nitride layer 61. The mask layer 63 may be formed of an amorphous carbon layer. The amorphous carbon layer may be formed using a CVD process. The amorphous carbon layer may be formed having a thickness of about 2000 Å to 5000 Å. The deposition process may be performed using a low temperature process at a temperature of 400° C. or lower. The deposition process may be performed using a low temperature process in a range of 200° C. to 400° C. As a result, characteristics of the metal nitride layer 61 may not be affected by deposition heat.

A photosensitive layer pattern 67 may be formed on the substrate having the mask layer 63 to cover the PMOS region P of the peripheral region II. The photosensitive layer pattern 67 may expose the cell region I and the NMOS region N of the peripheral region II. An anti-reflective coating layer 65 may be interposed between the mask layer 63 and the photosensitive layer pattern 67. The anti-reflective coating layer 65 may be a SiON layer. The anti-reflective coating layer 65 may be formed having a thickness of about 500 Å.

Although not shown in the drawing, prior to forming the gate insulating layer 59, N-type or P-type impurities may be selectively implanted into the substrate having the wells in order to control a threshold voltage of a transistor. The implanted impurities may be activated by a thermal treatment process.

As illustrated in FIG. 2C, the mask layer may be dry-etched using the photosensitive layer pattern as a mask, forming a mask 64 covering the PMOS region P of the peripheral region II. The mask 64 may expose the cell region I and the NMOS region N of the peripheral region II. The mask 64 may be an amorphous carbon mask. When dry-etching the mask layer, the photosensitive layer pattern and the anti-reflective coating layer may be removed.

As illustrated in FIG. 2D, an implantation process 81 may be performed to implant plasma type impurities into the surface of the substrate having the mask 64. The impurities may be a nitrogen gas or a gas including nitrogen. As a result, impurities may be selectively implanted into the cell region I and the NMOS region N of the peripheral region II of the metal nitride layer exposed by the mask 64. The portion 61a of the metal nitride layer, into which impurities may be implanted, demonstrates an increase etch rate during subsequent etch processes. For example, the implantation process 81 may be performed to increase an etch rate of the metal nitride layer for subsequent etching processes of the metal nitride layer 61. The impurity implantation process 81 may be selectively performed.

As shown in FIG. 2E, the metal nitride layer exposed by the mask 64 may be wet-etched after impurities are implanted thereto, selectively forming a preliminary metal nitride pattern 61b in the PMOS region P of the peripheral region II. The wet etching may be performed at a temperature of about 25° C. to 80° C. As described above, the portion of the metal nitride layer, into which impurities may be implanted, may have increased etching characteristics than other portions of the metal nitride layer. The portion of the metal nitride layer into which impurities are implanted may be more easily removed using the wet etch process.

As shown in FIG. 2F, the mask may be removed. The mask may be removed using an ashing process. The ashing process uses O₂ gas. As a result, damage to the gate insulating layer 59 and the surfaces of the active regions 52 due to etching may decrease.

As shown in FIG. 2G, a conductive layer 67 may be formed on the surface of the substrate having the preliminary metal nitride pattern 61b. The conductive layer 67 may be a polysilicon layer.

As shown in FIG. 2H, when etching the conductive layer 67, the preliminary metal nitride pattern 61b and the gate insulating layer 59 are sequentially formed. A cell gate electrode 67C may be formed in the cell region I, an NMOS gate electrode 67N in the NMOS region N and a PMOS gate electrode 68P in the PMOS region P. The cell gate electrode 67C and the NMOS gate electrode 67N may each be formed as a single conductive layer. The PMOS gate electrode 68P may be formed of a dual layer including a metal nitride pattern 61b′ and a conductive pattern 67P. A first conductivity type of impurities, or a second conductivity type of impurities, may be selectively implanted into the substrate having the respective gate electrodes. As a result, a first source/drain 69 may be formed in the substrate at both sides of the PMOS gate electrode 68P. A second source/drain 70 may be formed in the substrate at both sides of the cell gate electrode 67C. A third source/drain 71 may be formed in the substrate at both sides of the NMOS gate electrode 67N. Reference numeral 68 of FIG. 2H represents an insulating spacer. Reference numeral 59a represents a gate insulating layer, which may remain after etching.

Example embodiments of the present invention are also applicable to forming the cell gate electrode with a recessed shape.

According to example embodiments of the present invention, because the mask layer for etching the metal nitride layer may be formed using a low temperature process, characteristics of the metal nitride layer may not be affected. The metal nitride layer may be more easily etching during a subsequent process.

According to other example embodiments of the present invention, because the mask may be removed using an ashing process, damage on the surface of the high-k dielectric layer, during the removal of the mask, may decrease.

The foregoing is illustrative of the example embodiments of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein. What is claimed is:

1. A method of fabricating a semiconductor device comprising:
providing a semiconductor substrate having a first region and a second region;
forming a gate insulating layer, a metal nitride layer and an amorphous carbon layer sequentially on the substrate;
selectively etching the amorphous carbon layer, forming an amorphous carbon mask covering the first region; and
etching the metal nitride layer exposed by the amorphous carbon mask, forming a preliminary metal nitride pattern.

2. The method according to claim 1, wherein the first region is a PMOS region and the second region is an NMOS region.

3. The method according to claim 1, wherein the metal nitride layer is formed using a chemical vapor deposition (CVD) process, a physical vapor deposition (PVD) process or a sputtering process.

4. The method according to claim 1, wherein the metal nitride layer is formed with a thickness of about 50 Å to 150 Å.

5. The method according to claim 1, wherein the metal nitride layer is a TaN layer or a TiN layer.

6. The method according to claim 1, wherein the amorphous carbon layer is formed using a chemical vapor deposition (CVD) process.

7. The method according to claim 1, wherein the amorphous carbon layer is formed having a thickness of about 2000 Å to 5000 521 .

8. The method according to claim 6, wherein the deposition process is performed at a temperature of about 200° C. to 400° C.

9. The method according to claim 1, wherein the etching of the metal nitride layer includes performing a wet etching process.

10. The method according to claim 9, wherein the wet etching is performed at a temperature of about 25° C. to 80° C.

11. The method according to claim 1, wherein the removing of the amorphous carbon mask includes performing an ashing process.

12. The method according to claim 1, wherein the gate insulating layer is a high-k dielectric layer.

13. The method according to claim 12, wherein the high-k dielectric layer is formed of a compound selected from the group consisting of HfO₂, HfSiO, Al₂O₃, TiO₂, Ta₂O₅ and ZrO₂.

14. The method according to claim 1 further comprising, implanting nitrogen impurities into the metal nitride layer exposed by the amorphous carbon mask, after forming the amorphous carbon mask.

15. The method according to claim 1 further comprising,
forming a conductive layer on the substrate having the preliminary metal nitride pattern after removing the amorphous carbon mask; and
sequentially etching the conductive layer to form a conductive pattern and the preliminary metal nitride pattern to form a metal nitride pattern,
wherein a first gate electrode having the metal nitride pattern and the conductive pattern doubly stacked is formed in the first region and a second gate electrode is formed in the second region, the second gate electrode formed of the conductive pattern.

16. The method according to claim 15 further comprising, forming source/drain regions in the substrate on sides of the first gate electrode and the second gate electrode, after forming the first gate electrode and the second gate electrode.

17. The method of claim 2 further comprising,
removing the amorphous carbon mask, after etching the metal nitride layer;
forming a conductive layer on the surface of the substrate having the preliminary metal nitride pattern; and
etching the conductive layer and the preliminary metal nitride pattern to form a PMOS gate electrode in the PMOS region and the conductive layer to form an NMOS gate electrode in the NMOS region.

18. The method according to claim 17, wherein the gate insulating layer is a high-k dielectric layer formed of a compound selected from the group consisting of HfO₂, HfSiO, TiO₂, Ta₂O₅ and ZrO₂.

19. The method according to claim 17, wherein the metal nitride layer is a TaN layer or a TiN layer.

20. The method according to claim 17, wherein the amorphous carbon layer is formed using a chemical vapor deposition (CVD) process.

21. The method according to claim 20, wherein the deposition process is performed at a temperature of about 200° C. to 400° C.

22. The method according to claim 17, wherein the amorphous carbon layer is formed having a thickness of about 2000 Å to 5000 Å.

23. The method according to claim 17, wherein removing the amorphous carbon mask includes performing an ashing process.

24. The method according to claim 17 further comprising, forming source/drain regions in the substrate on sides of the PMOS gate electrode and the NMOS gate electrode.

25. The method according to claim 17 further comprising, implanting nitrogen impurities into the metal nitride layer exposed by the amorphous carbon mask, after forming the amorphous carbon mask.
